(19) United States
(12) Patent Application Publication
(10) Pub. No.: US 2009/0134510 A1
(43) Pub. Date: May 28, 2009

(54) SEMICONDUCTOR PACKAGE AND METHOD OF FABRICATING THE SAME, AND ELECTRONIC DEVICE USING THE SEMICONDUCTOR PACKAGE

(76) Inventors: Hak-Sung KIM, Cheonan-si (KR); Ho-Geon Song, Seoul (KR); Seok-Won JEONG, Cheonan-si (KR)

Correspondence Address: STANZIONE & KIM, LLP, 919 18TH STREET, N.W., SUITE 440, WASHINGTON, DC, 20006, US

(21) Appl. No.: 12/209,428

(22) Filed: Sep. 12, 2008

(30) Foreign Application Priority Data
Sep. 14, 2007 (KR) 2007-93674

(51) Int. Cl. H01L 23/528; H01L 21/768

(52) U.S. Cl. 257/698; 438/108; 257/E23.151; 257/E21.575

(57) ABSTRACT

A semiconductor package and method of fabricating the same. The semiconductor package includes a first semiconductor package, a second semiconductor package stacked on the first semiconductor package, and a first electrical connector interposed between the first and second semiconductor packages to electrically connect the first and second semiconductor packages.

### CROSS-REFERENCE TO RELATED APPLICATIONS

This application claims priority under 35 U.S.C § 119 to Korean Patent Application No. 10-2007-0093674, filed on Sep. 14, 2007, in the Korean Intellectual Property Office, the entire contents of which are incorporated by reference.

### BACKGROUND OF THE INVENTION

1. Field of the Invention

The present general inventive concept relates to a semiconductor device, and more specifically, to a semiconductor package and method of fabricating the same, and electronic device using semiconductor package.

2. Description of the Related Art

Highly integrated electronic devices with multi-functions and a small volume have been used. In order to realize an electronic device with a large number of semiconductor chips mounted, a multi-chip packaging (MCP) method which integrates various kinds of semiconductor chips in one package, and a package-on-package (POP) method which stacks a number of packages are widely used. For such packaging method, it is essential that the printed circuit boards (PCB) be electrically connected to each other, and the semiconductor chips and PCBs be electrically connected.

FIG. 1 is a cross-sectional view illustrating a conventional semiconductor package 10. Referring to FIG. 1, the semiconductor package 10 includes a first semiconductor chip 12 on which a first PCB 11 is mounted and a second semiconductor chip 22 on which a second PCB 21 is mounted. Molding layers 15 and 25 may be further formed on the semiconductor package 10.

The first PCB 11 includes a first window 16 through which a portion of the first semiconductor chip 12 is exposed. A first interconnection 13 is disposed through the first window and electrically connects the first semiconductor chip 12 to the first PCB 11. Similarly, the second PCB 22 includes a second window 26 through which a portion of the second semiconductor chip 22 is exposed. A second interconnection 23 is disposed through the second window 26 and electrically connects the second semiconductor chip 22 to the second PCB 21. A plurality of external connection terminals 15 such as solder balls are attached to the first PCB 11.

The first PCB 11 and the second PCB 21 are electrically connected to each other by a plurality of solder balls 14. Therefore, an attaching process of the solder balls 14 may cause poor productivity. In addition, defects or failures in wetting the solder balls 14 may occur due to warpages of the PCBs 11 and 21, which could deteriorate reliability of the semiconductor package 10.

### SUMMARY OF THE INVENTION

The present general inventive concept provides a semiconductor package and a method of fabricating the same, and electronic devices using the semiconductor package.

Additional aspects and utilities of the present general inventive concept will be set forth in part in the description which follows and, in part, will be obvious from the description, or may be learned by practice of the general inventive concept.

The foregoing and/or other aspects and utilities of the present general inventive concept may be achieved by providing a semiconductor package including a first semiconductor package, a second semiconductor package stacked on the first semiconductor package, and a first electrical connector interposed between the first and second semiconductor packages to electrically connect the first and second semiconductor packages, the first electrical connector filling an empty space between the first and second semiconductor packages.

The foregoing and/or other aspects and utilities of the present general inventive concept may also be achieved by providing a method of fabricating semiconductor package may include: providing a first and a second semiconductor packages; disposing an electrical connector between the first and second semiconductor packages; and performing thermo-compression to the electrical connector to electrically connect the first and second semiconductor packages by the electrical connector.

The foregoing and/or other aspects and utilities of the present general inventive concept may also be achieved by providing an electronic device including the semiconductor package.

The foregoing and/or other aspects and utilities of the present general inventive concept may also be achieved by providing an electronic device including the semiconductor package fabricated according to the method of fabricating the semiconductor packages.

### BRIEF DESCRIPTION OF THE DRAWINGS

These and/or other aspects and utilities of the present general inventive concept will become apparent and more readily appreciated from the following description of the embodiments, taken in conjunction with the accompanying drawings of which:

FIG. 1 is a cross-sectional view illustrating a conventional semiconductor package.

FIG. 2A is a cross-sectional view illustrating a semiconductor package according to an exemplary embodiment of the present general inventive concept.

FIG. 2B is a cross-sectional view illustrating a semiconductor package according to an exemplary embodiment of the present general inventive concept.

FIG. 2C is a cross-sectional view illustrating a semiconductor package according to an exemplary embodiment of the present general inventive concept.

FIG. 3A and FIG. 3B are cross-sectional views of portions of FIG. 2A.

FIG. 4A is a cross-sectional view illustrating a semiconductor package according to an exemplary embodiment of the present general inventive concept.

FIG. 4B is a cross-sectional view illustrating a semiconductor package according to an exemplary embodiment of the present general inventive concept.

FIGS. 5A, 5B and 5C are plan views of portions of FIG. 4A.

FIG. 6A is a cross-sectional view illustrating a semiconductor package according to an exemplary embodiment of the present general inventive concept.

FIG. 6B is a cross-sectional view illustrating a semiconductor package according to an exemplary embodiment of the present general inventive concept.

FIG. 7 is a cross-sectional view of a portion of FIG. 6A.

FIG. 8A and FIG. 8B are examples of electronic devices having the semiconductor packages according to the exemplary embodiments of the present general inventive concept.

FIG. 9 is a view illustrating an electronic device according to an embodiment of the present general inventive concept.

FIG. 10 is a flowchart illustrating a method of forming a semiconductor package.

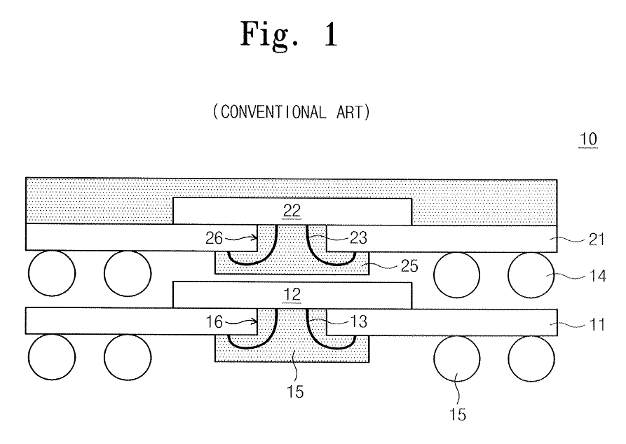

### DETAILED DESCRIPTION OF THE PREFERRED EMBODIMENTS

Reference will now be made in detail to the embodiments of the present general inventive concept, examples of which are illustrated in the accompanying drawings, wherein like reference numerals refer to the like elements throughout. The embodiments are described below in order to explain the present general inventive concept by referring to the figures.

It will be understood that when an element or layer is referred to as being “on”, “connected to” or “coupled to” another element or layer, it can be directly on, connected or coupled to the other element, or layer or intervening elements or layers may be present. In contrast, when an element is referred to as being “directly on,” “directly connected to” or “directly coupled to” another element or layer, there are no intervening elements or layers present. As used herein, the term “and/or” includes any and all combinations of one or more of the associated listed items.

It will be understood that, although the terms first, second, third etc. may be used herein to describe various elements, components, regions, layers and/or sections, these elements, components, regions, layers and/or sections should not be limited by these terms. These terms are only used to distinguish one element, component, region, layer or section from another region, layer or section. Thus, a first element, component, region, layer or section discussed below could be termed a second element, component, region, layer or section without departing from the teachings of the present general inventive concept.

Spatially relative terms, such as “beneath”, “below”, “bottom”, “lower”, “above”, “top”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly. Also, as used herein, “lateral” refers to a direction that is substantially orthogonal to a vertical direction.

The terminology used herein is for the purpose of describing particular embodiments only, and is not intended to be limiting of the present general inventive concept. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments of the present general inventive concept are described herein with reference to cross-section illustrations that are schematic illustrations of idealized embodiments (and intermediate structures) of the invention. As such, variations from the shapes of the illustrations as a result, for example, of fabricating techniques and/or tolerances, are to be expected. Thus, embodiments of the present invention should not be construed as limited to the particular shapes of regions illustrated herein but are to include deviations in shapes that result, for example, from fabricating. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the present invention.

Unless otherwise defined, all terms (including technical and scientific terms) used herein have the same meaning as commonly understood by one of ordinary skill in the art to which this general inventive concept belongs. Accordingly, these terms can include equivalent terms that are created after such time. It will be further understood that terms, such as those defined in commonly used dictionaries, should be interpreted as having a meaning that is consistent with their meaning in the present specification and in the context of the relevant art, and will not be interpreted in an idealized or overly formal sense unless expressly so defined herein.

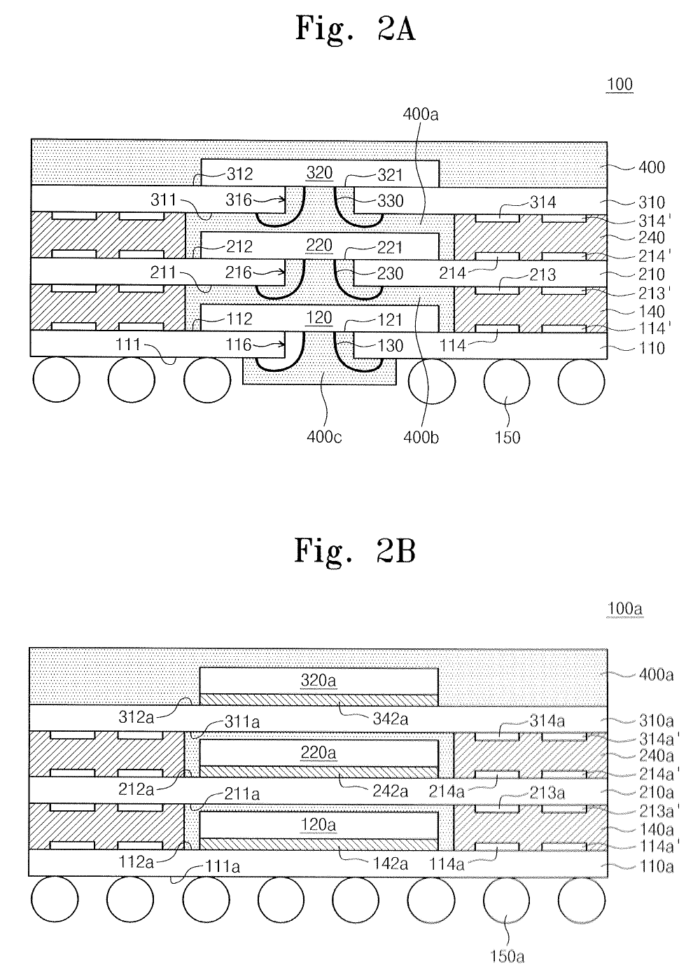

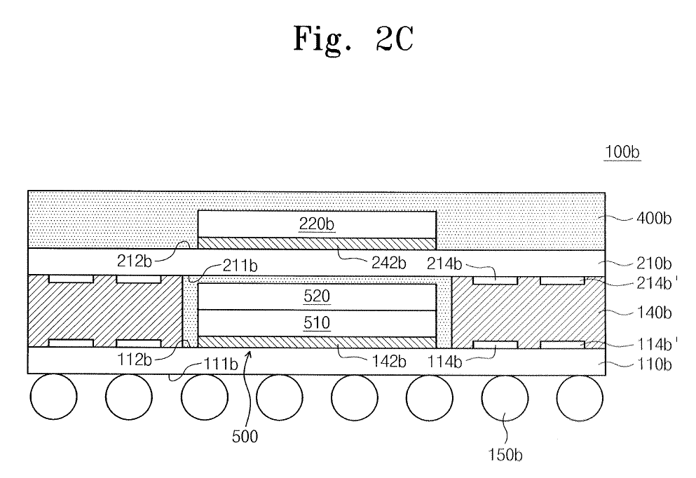

Referring to FIG. 2A, a semiconductor package 100 of an exemplary embodiment may have so called POP (Package On Package) structure. For example, the semiconductor package 100 may include a first semiconductor chip 120 on which a first substrate 110 is mounted and a second semiconductor chip 220 on which a second substrate 210 is mounted. The second substrate 210 may stacked on the first substrate 110. A first conductive film 140 may be interposed between the first and second substrate to electrically connect the first substrate 110 to the second substrate 210.

In an implementation, the first substrate 110 may be a PCB which includes a first surface 111 and a second surface 112 opposite to the first surface 111. A plurality of substrate pads 114 and 114′ may be provided on the second surface 112 of the first substrate 110 to be connected to the first semiconductor chip 120 through the bonding wire 130 and an internal conductive circuit lines formed therein. A plurality of external connection terminals 150 such as solder balls may be attached to the first surface 111 of the first substrate 110. The first substrate 110 and the first semiconductor chip 120 may form a board-on-chip (BOC) structure. The first substrate 110 may have a first window 116 penetrating a portion of the first substrate 110. The first window 116 may expose a portion of the first semiconductor chip 120, e.g., an active surface 121. A first bonding wire 130 may be disposed through the first window 116. One end of the first bonding wire 130 may contact the first semiconductor chip 120, and the other end thereof may contact the first substrate 110, thereby the first semiconductor chip 120 and the first substrate 110 are electrically connected to each other.

Similarly, the second semiconductor chip 220 and the second substrate 210 may also form the board-on-chip (BOC) structure. The second substrate 210 may be a PCB which includes a first surface 211 and a second surface 212 opposite to the first surface 211. The second substrate 210 and the second semiconductor chip 220 may be electrically connected to each other by a second bonding wire 230 passing through a second window 216 through which a portion of an active surface 221 of the semiconductor chip 220 is exposed. A plurality of substrate pads 213 and 213′ are provided on the first surface 211 of the second substrate 210 to be connected to the second semiconductor chip 220 through the bonding wire 230 and an internal conductive circuit lines formed therein, and a plurality of substrate pads 214 and 214′ may be provided on the second surface 212 of the second substrate 210 to be connected to the second semiconductor chip 220 and/or other substrate pads through the bonding wire 230 and an internal conductive circuit lines formed therein.

A first conductive film 140 may be interposed between the first substrate 110 and the second substrate 210. The first conductive film 140 may be electrically connected to the substrate pads 114 and 114′ of the first substrate 110 and the substrate pads 213 and 213′ of the second substrate 210, thereby the first substrate 110 may be electrically connected to the second substrate 210. Each of the substrate pads 114 and 114′ is electrically connected to each of the substrate pads 213 and 213′, respectively. In an implementation, an anisotropic electrical connection may be made in the first conductive film 140, which the substrate pad 114 is electrically connected to the substrate pad 213 but not electrically connected to the substrate pad 213′. Similarly, the substrate pad 114′ is electrically connected to the substrate pad 213′ but not electrically connected to the substrate pad 213. The second substrate 210 and the first substrate 110 must be adhered to tightly.

As described above, the first conductive film 140 may have both adhesiveness and electrically conductive characteristic to a specific direction. An adhesive anisotropic conductive film (ACF) may be selected as the first conductive film 140. The ACF may be a lead-free and environmentally friendly epoxy system. Such anisotropic electrical connection may be achieved by performing thermo-compression process during a process of stacking the second substrate 210 on the first substrate 110 after the first conductive film 140 is interposed, and then compression may be applied vertically between the first substrate 110 and the second substrate 210.

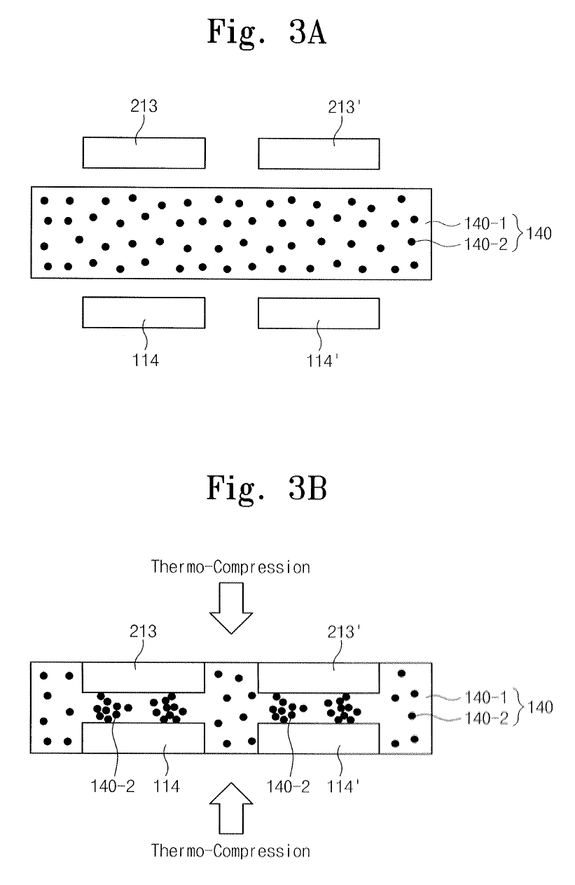

Referring to FIG. 3A, the first conductive film 140 may have a structure in which a plurality of conductive particles 140-2 are dispersed in an adhesive matrix 140-1. The same applies to a second conductive film 240.

Referring to FIG. 3B, when compression, e.g., thermo-compression, may be applied, the substrate pads 114 and 213 may vertically compress the first conductive film 140. Accordingly, a portion of the conductive particles 140-2 may be disposed densely between the substrate pads 114 and 213 in the same direction as the compression direction to form one or more electrical conductive channels (connections) in the vertical direction to correspond to the substrate pads. A vertically electrical connection between the substrate pad 114 and the substrate pad 213 may be achieved by the densely disposed conductive particles 140-2. The same applies to the electrical connection between the substrate pad 114′ and the substrate pad 213′. In order to achieve the electrical connection more easily, as depicted in FIG. 2A, the substrate pad 114 may protrude from the second surface 112 of the first substrate 110 to be connected to the third semiconductor chip 320 through the bonding wire 330 and an internal conductive circuit lines formed therein and also to be connected to other substrate pads of other substrates. It may be the same for the other substrate pads 114′, 213 and 213′.

Referring back to FIG. 2A, solder balls may be disposed between the first substrate 110 and the second substrate 210 to electrically connect the first and the second substrates 110 and 210. However, in the present embodiment, when the first conductive film 140 is used, the process forming solder balls can be skipped or eliminated so as to simplify process and shorten a process time. The first conductive film 140 may fill most of the empty space between the first substrate 110 and the second substrate 210, which may improve mechanical durability of the semiconductor package 100.

It is possible that a third substrate 310 mounted on a third semiconductor chip 320 may be further stacked on the second substrate 210. The third semiconductor chip 320 and the third substrate 310 may form a board-on chip (BOC) structure. The third substrate 310 may be a PCB. The third substrate 310 may be electrically connected to the third semiconductor chip 320 by a third bonding wire 330 passing through a third window 316 through which a portion of an active surface 321 of the semiconductor chip 220 is exposed. A plurality of substrate pads 314 and 214′ may be provided on a first surface 311 of the third substrate 310, and a second surface 312 may be in contact with the third semiconductor chip 320. A second conductive film 240 may be interposed between the second substrate 210 and the third substrate 310. The second conductive film 240 may electrically connect the substrate pads 214 and 214′ to the substrate pads 314 and 314′ of the third substrate 310, respectively. An adhesive anisotropic conductive film may be selected as the second conductive film 240.

Additionally, a molding layer 400 which is made of an epoxy molding compound (EMC) may be further formed on the semiconductor package 100. Therefore, mechanical durability and reliability of the semiconductor package 100 may be obtained. The molding layer 400 may occupy one or more empty spaces between the first to third substrates 110, 210, and 310, for example, spaces 400a, 400b, and/or 400c, so as to improve mechanical durability and reliability of the semiconductor package 100.

The semiconductor package 100 may be fabricated by performing the following processes. The first substrate 110 electrically connected to the first semiconductor chip 120 may be prepared, and the second substrate 210 electrically connected to the second semiconductor chip 220 may be prepared. A preparing operation of the first substrate 110 may be realized by mounting the first substrate 110 on the first semiconductor chip 120, and by forming the first bonding wire 130 disposed through the first window 116 to electrically connect the first semiconductor chip 120 so as to the first substrate 110. Similarly, a preparing operation of the second substrate 210 may be realized by mounting the second substrate 210 on the second semiconductor chip 220, and by forming the second bonding wire 230 disposed through the second window 216 so as to electrically connect the second semiconductor chip 220 to the second substrate 210.

The third substrate 310 is mounted on the third semiconductor chip 320, and the third bonding wire 330 is formed to be disposed through a third window 316 so as to electrically connect the third substrate 310 to the third semiconductor chip 320.

The second substrate 210 may be stacked on the first substrate 110. The first conductive film 140 may be interposed between the first and second substrate 110 and 210. After or while the second substrate 210 is stacked on the first substrate 110, vertical compression as well as heat (thermo-compression) may be applied to the first substrate 110 and the second substrate 210. Therefore, the substrate pads 114 and 114′ may be electrically connected to the substrate pads 213 and 213′, respectively, by means of the first conductive film 140.

The third substrate 310 may be further stacked on the second substrate 210. The second conductive film 240 may be interposed between the second and third substrate 210 and 310. After or while the third substrate 310 is stacked on the second substrate 210, vertical compression as well as heat may be applied to the second substrate 210 and the third substrate 310. Thus, the substrate pads 214 and 214′ may be electrically connected to the substrate pads 314 and 314′, respectively, by means of the second conductive film 240.

External connection terminals 150 may be attached to the first surface 111 of the first substrate 110. The external connection terminals 150 may be a plurality of solder balls, a plurality of bumps, etc.

Additionally, the molding layer 400 may be further formed. A molding process may be performed after the semiconductor package 100 is provided. Alternatively, the molding process may be performed in each preparation operation of the first to third substrates 110, 210 and 310. During the molding process, the molding layer 400 may be formed to fill the empty space between the first to third substrates 110, 210, and 310 so as to improve mechanical durability of the semiconductor package 100.

Referring to FIG. 2B, a semiconductor package 100a may be similar to the semiconductor package 100 of FIG. 2A, and may further include a first substrate 110a electrically connected to a first semiconductor chip 120a and a second substrate 210a electrically connected to a second semiconductor chip 220a. The second substrate 210a may be stacked on the first substrate 110a. Afirst conductive film 140a may be interposed between the first substrate 110a and the second substrate 210a such that the first and second substrates 110a and 210a may be electrically connected to each other.

A first sub-conduction film 142a may be interposed between the first semiconductor chip 120a and the first substrate 110a to electrically connect to each other. Similarly, a second sub-conductive film 242a may be interposed between the second semiconductor chip 220a and the second substrate 210a to electrically connect to each other.

In an implementation, the first substrate 110a may be a PCB. A plurality of external connection terminals 150a such as solder balls may be attached to the first surface 111a of the first substrate 110a, and a plurality of substrate pads 114a and 114a′ may be provided on the second surface 112a of the second substrate 112a. Similarly, a plurality of substrate pads 213a and 213a′ may be provided on a first surface 211a of the second substrate 210a, and a plurality of substrate pads 214a and 214a′ may be provided on a second surface 212a of the second substrate 210a. The first and second sub-conductive films 142a and 242a may comprise adhesive anisotropic conductive films. The structure and anisotropic electrical connection of the first and second sub-conductive films 142a and 242a may be identical or similar to the descriptions set forth with reference to FIGS. 3A and 3B.

Afirst conductive film 140a may be interposed between the first substrate 110a and the second substrate 210a. The first conductive film 140a may electrically connect the first substrate 110a to the second substrate 210a, the substrate pad 114a to the substrate pad 213a, and the substrate pad 114a′ to the substrate pad 213a′. As described above with reference to FIG. 2A, an adhesive anisotropic conductive film may be selected as the first conductive film 140a. As described above with reference to FIGS. 3A and 3B, an anisotropic electrical connection may be achieved by vertically applying compression and heat to the first and second substrates 110a and 210a.

A third substrate 310a, such as a PCB, may be electrically connected to a third semiconductor chip 320a and may be further stacked on the second substrate 210a. A second conductive film 240a may be interposed between the second and third substrates 210a and 310a. A third sub-conductive film 342a may be interposed between the third substrate 310a and the third semiconductor chip 320a. An adhesive anisotropic conductive film may be selected as the third sub-conductive film 342a. A plurality of substrate pads 314a and 314a′ may be provided on a first surface 311a of the third substrate 310a. A second surface 312a may be electrically connected to the third semiconductor chip 320a by means of the third sub-conductive film 342a.

The second conductive film 240a may be interposed between the second substrate 210a and the third substrate 310a. The second substrate 310a and the third substrate 310a are bonded together, the substrate pad 214a and the substrate pad 314a are electrically connected, and the substrate pad 214a′ and the substrate pad 314a′ are electrically connected, by means of the second conductive film 240a. As described above with reference to FIG. 2A, an adhesive anisotropic conductive film may be selected as the first conductive film 140a. As described above, an anisotropic conductive film may be selected as the second conductive film 240a. An anisotropic electrical connection may be achieved by applying compression and heat vertically to the first and second substrate 210a and the third substrate 310a. A molding layer 400a made of an epoxy molding compound (EMC) may be further included in the semiconductor package 100a.

As described above, the semiconductor package 100a does not require solder balls between the first to third substrates 110a, 210a and 310a, and also does not require bonding interconnection between each of the first to third semiconductor chips 120a, 220a and 320a and between each of the first to third substrates 110a, 210a and 310a. Accordingly, the process may be simplified and process time may be shortened.

A process of fabricating the semiconductor package 100a of FIG. 2B may be similar to fabricating semiconductor package 100 described with reference to FIG. 2A, however, operations of preparing the first and second substrates 110a and 210a may be different. Preparing the first substrate 110a may be done by mounting the first substrate 110a on the first semiconductor chip 110a with the sub-conductive film 142a interposed therebetween. Preparing the second substrate 210a may be the same. A third substrate 310a may be further provided. A molding process may be performed after the semiconductor package 100a is formed, or during the operation of preparing the first to third substrates 110a, 210a and 310a.

Referring to FIG. 2C, a semiconductor package 100b may be similar to the semiconductor package 100 of FIG. 2A or the semiconductor package 100a of FIG. 2B, and may include a first substrate 110b and a second substrate 210b electrically connected by means of a conductive film 140b. The first substrate 110b may be electrically connected to a sub-semiconductor package 500 with a first sub-conductive film 142b interposed therebetween, and the second substrate 210b may be electrically connected to a semiconductor chip 220b with a second sub-conductive film 242b interposed therebetween. Alternatively, the second substrate 210b may be electrically connected to a semiconductor package similar to a sub-semiconductor package 500. The structure of the above described semiconductor package 100b may be applied to the respective semiconductor packages to be described below.

For example, the first substrate 110b, for example a PCB, may be electrically connected to the sub-semiconductor package 500, and the electrical connection may be made by means of the first sub-conductive film 142b. The sub-semiconductor package 500 may include a sub-substrate 510, e.g., a PCB, electrically connected to a sub-semiconductor chip 520 using terminals or pads disposed therebetween as a package. The sub-substrate 510 may be electrically connected to the first substrate 110b by the first sub-conductive film 142b. The first sub-conductive film 142b may be an adhesive anisotropic conductive film. External connection terminals 150b, for example, a plurality of solder balls, may be attached to a first surface 111b of the first substrate 110b, and a plurality of substrate pads 114b and 114b′ may be provided on a second surface 112b.

The second substrate 210b, for example, a PCB, may be electrically connected to the semiconductor chip 220b by means of the second conductive film 242b. The second sub-conductive film 242b may be an adhesive anisotropic conductive film. A plurality of substrate pads 214b and 214b′ may be provided on a first surface 211b of the second substrate 210b, and the second surface 212b may be electrically connected to the semiconductor chip 220b by means of the second sub-conductive film 242b.

A conductive film 140b may be interposed between the first substrate 110b and the second substrate 210b. The first substrate 110b and the second substrate 210b may be bonded together by the conductive film 140b, such that the substrate pad 114b and the substrate pad 214b may be electrically connected, and the substrate pad 114b′ and the substrate pad 214b′ may be electrically connected. As described above with reference to FIG. 2A, an adhesive anisotropic conductive film may be selected as the conductive film 140b, and the anisotropic electrical connection may be achieved by performing a thermo-compression process. A molding layer 400b made of an epoxy molding compound (EMC) may be further included in the semiconductor package 100b. As illustrated in FIG. 2A, and FIG. 2B, one or more substrate such as a PCB electrically connected to a semiconductor chip or a semiconductor package may be further stacked on the second substrate 210b.

Process of fabricating the semiconductor package 100b may be similar to the fabricating process of the above semiconductor package 100a described with reference to FIG. 2B, but a preparing step of the first substrate 110b may be different. For example, the preparing step of the first substrate 110b may include mounting a second surface 112b of the first substrate 110b with the first sub-conductive film 142a interposed therebetween.

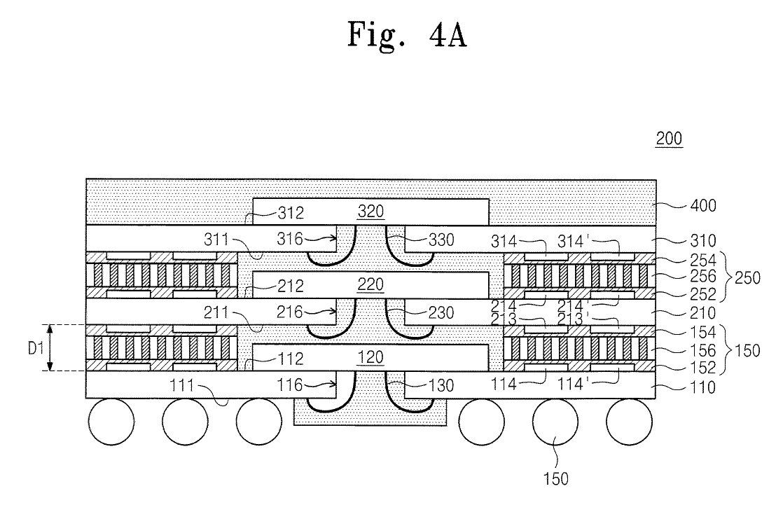

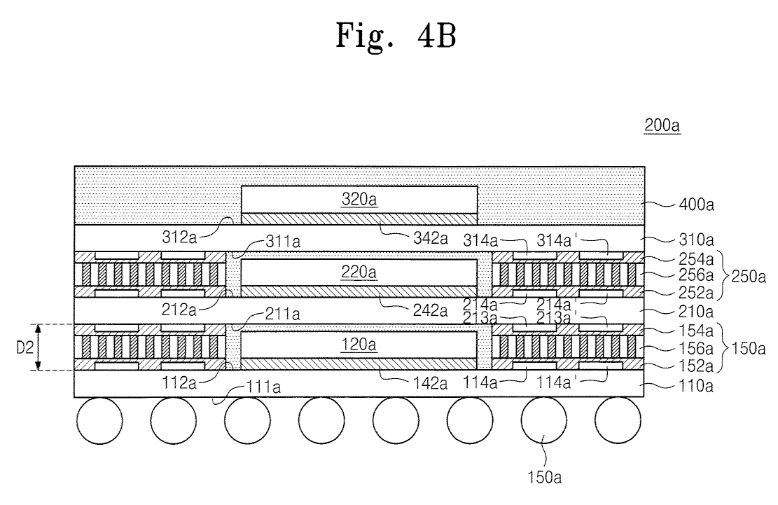

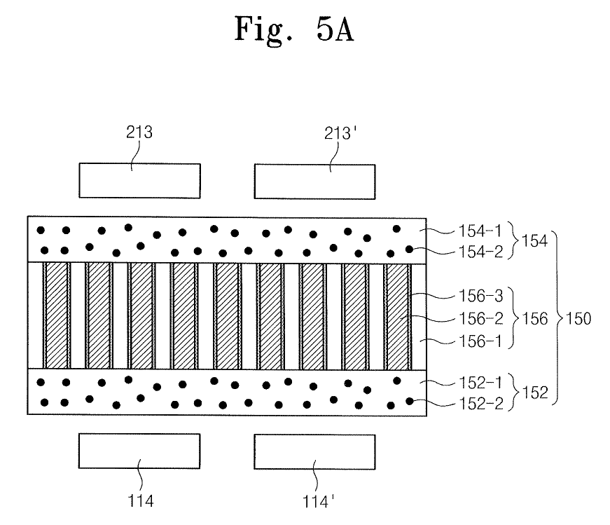

Referring to FIG. 4A, a semiconductor package 200 according to an exemplary embodiment may be similar to the semiconductor package 100 described in FIG. 2A except for a first electrical connector 150 and/or a second electrical connector 250.

In the semiconductor package 100 of the exemplary embodiment of FIG. 2A, the first conductive film 140 is selected to electrically connect the first substrate 110 to the second substrate 210. However, in a case a distance D1 between the first substrate 110 and the second substrate 210 is relatively large, it may be difficult to select the first conductive film 140 due to the limit in the thickness of the first conductive film 140. In order to solve this problem, for the semiconductor package 200, the first electrical connector 150 may be selected to be usable with the semiconductor package 200 of FIG. 4A, instead of the first conductive film 140, regardless of the distance D1.

The first substrate 110 and the second substrate 210 may be bonded together and electrically connected by means of the first electrical connector 150. The substrate pad 114 may be electrically connected to the substrate pad 213 and the substrate pad 114′ may be electrically connected to the substrate pad 213′ by means of the first electrical connector 150. In order to configure the above electrical connection, the first electrical connector 150 may be constructed as will be described.

The first electrical connector 150 may include a first conductive film 152 and a second conductive film 154 which bond and electrically connect vertically the first and second substrates 110 and 210, and also may include a conductive block 156 for electrical connection in a vertical direction between the first conductive film 152 and the second conductive film 154. The first and second films 152 and 154 may be adhesive, but the conductive block 156 may be non-adhesive. The first conductive film 152 may be attached to a second surface 112 of the first substrate 110, and the second conductive film 154 may be attached to a first surface 211 of the second substrate 210. The conductive block 156 may be interposed between the first and second conductive films 152 and 154.

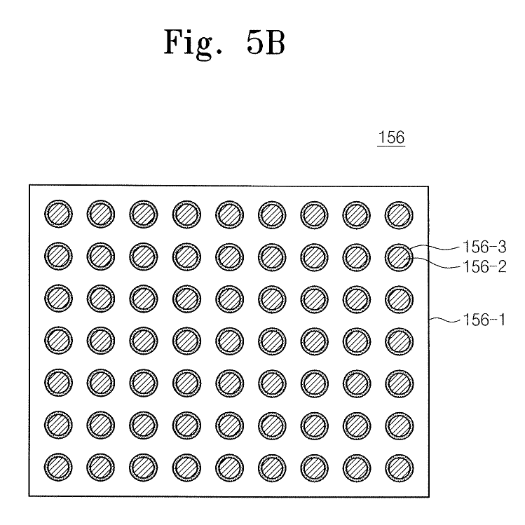

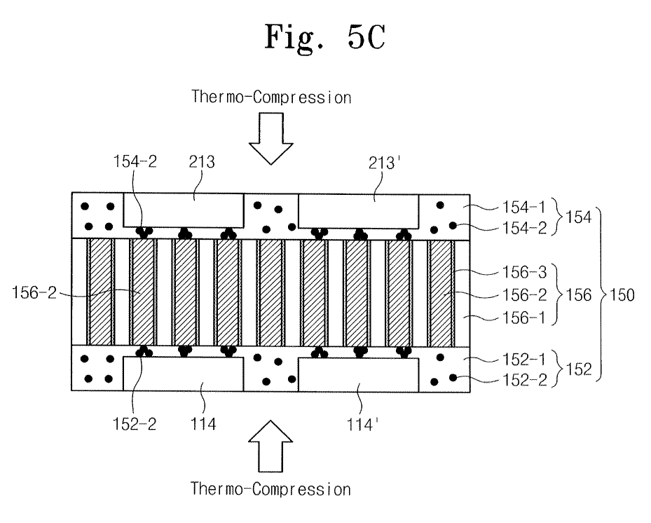

Referring to FIGS. 5A and 5B, the first conductive film 152 may be an adhesive anisotropic conductive film (ACF) in which a plurality of conductive particles 152-2 are dispersed in an adhesive matrix 152-1. The second conductive film 154 may also be an adhesive anisotropic conductive film in which a plurality of conductive particles 152-2 are dispersed in an adhesive matrix 154-1. The non-adhesive conductive block 156 may include a plurality of conductive pillars 156-2 extended vertically in a matrix 156-1. The matrix 156-1 may be a ductile conductive material such as polymer. Both ends of the conductive pillar 156-2 may be in contact with the respective first and second conductive films 152 and 154 to enable vertical electrical connection between the first and the second conductive films 152 and 154. Accordingly, the conductive pillars 156-2 may function as electrical connection paths between the substrate pads 114 and 114′ and the substrate pads 213 and 213′. Additionally, an insulation layer 156-3 may be coated on sidewall of the conductive pillars 156-2. The insulation layer 156-3 may prohibit the vertical electrical connection between the conductive pillars 156-2. Accordingly, the insulation layer 156-3 may prohibit electrical connection between the substrate pad 114 and the substrate pad 213′, and electrical connection between the substrate pad 114′ and the substrate pad 213. The above anisotropic electrical connection may be achieved by performing the thermo-compression process described in FIG. 2A.

Referring to FIG. 5C, when thermo-compression is performed, the substrate pads 114 compresses the first conductive film 152 vertically. Accordingly, a portion of the conductive particles 152-2 are disposed densely to form one or more electrical channels (connections) to correspond to the substrate pads and to electrically connect the substrate pad 114 and conductive pillars 156-2. The same may be applied to the substrate pad 213. The substrate pad 114 and substrate pad 213 may be electrically connected vertically. It may be the same for the electrical connection between the substrate pad 114′ and the substrate pad 213′.

Referring back to FIG. 4A, a third substrate 310 electrically connected to a third semiconductor chip 320 may be further stacked on the second substrate 210 with a second electrical connector 250 interposed therebetween. The substrate pad 214 and substrate pad 314 may be electrically connected to each other and the substrate pad 214′ may be electrically connected to substrate pad 314′, by the second electrical connector 250. Similar to the first electrical connector 150, the second electrical connector 250 may include adhesive conductive films 252 and 254 which have adhesiveness and vertical electrical conductive characteristics, and non-adhesive conductive block 256 interposed between the conductive films 252 and 254 to electrically connect vertically between the second and third substrates 210 and 310. The configuration of conductive films 252 and 254 and conductive blocks 256 and anisotropic electrical connection characteristics may be the same as described with reference to FIG. 5A to FIG. 5C.

Referring to FIG. 4B, the semiconductor package 200a may be similar to the semiconductor package 200 of FIG. 2B except for a first electrical connector 150a and/or a second electrical connector 250.

For the semiconductor package 200a, a first conductive film 140a which may have a limited thickness as in FIG. 2B is not selected but the first electrical connector 150a is selected, regardless of the distance D2. The substrate pad 114a and a substrate pad 213a may be vertically electrically connected to each other and the substrate pad 114a′ may be vertically electrically connected to the substrate pad 213a′, by means of the first electrical connector 150a.

The first electrical connector 150a, as described with reference to FIG. 4A, may include adhesive conductive films 152 and 154a which bond and electrically connect vertically the first substrate 110a to the second substrate 210a, and also include a non-adhesive conductive block 156a for electrically connecting vertically. The anisotropic electrical connection characteristics of the first electrical connector 150a may be identical to that described in FIGS. 5A to 5C.

A third substrate 310a may be further stacked on the second substrate 210a with a second electrical connector 250a interposed therebetween. The third substrate 310a may be electrically connected to a third semiconductor chip 320a with a third sub-conductive film 342a. The configuration of the second electrical connector 250a and anisotropic electrical connection characteristics may be identical to that of the first electrical connector 150a.

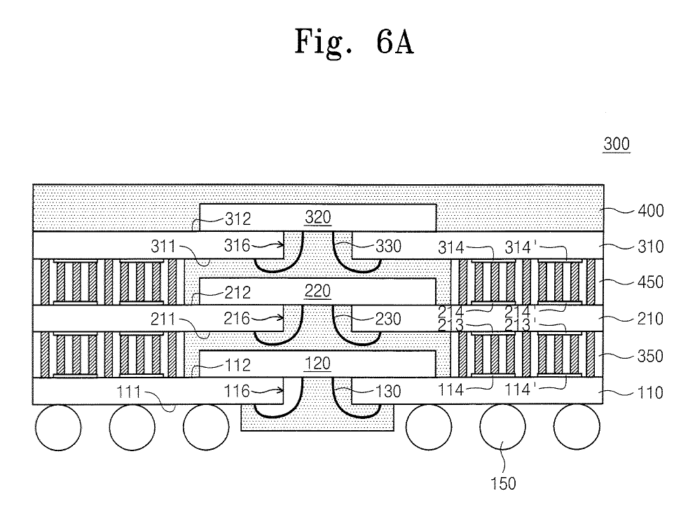

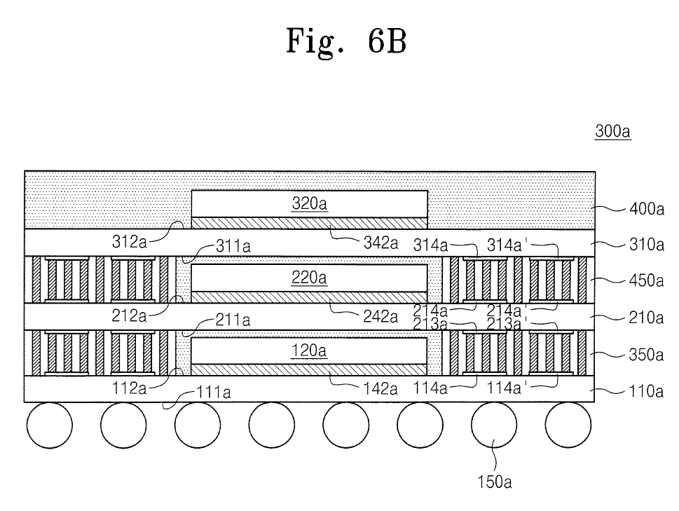

Referring to FIG. 6A, a semiconductor package 300 of an exemplary embodiment may be similar to the semiconductor package 200 of FIG. 4A except for a first conductive block 350 and/or a second conductive block 450.

The first electrical connector 150 of FIG. 4A may have adhesive conductive films 152 and 154 in order to bond the first substrate 110 and the second substrate 210 together. However, the first conductive block 350 may have adhesive characteristic inherently, and thus, the adhesive conductive films 152 and 154 may not be required. The configuration of the first conductive block 350 for adhesiveness and electrical connection may be as described below.

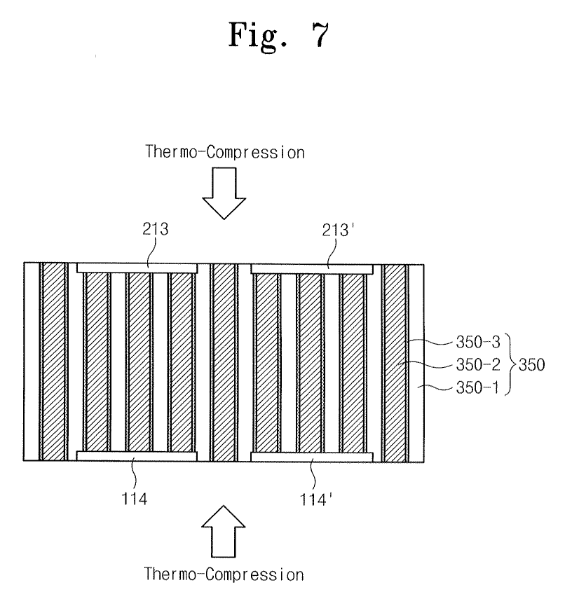

Referring to FIG. 7, the first conductive block 350 may include an adhesive matrix 350-1. The adhesive matrix 350-1 may include an insulative ductile material, e.g., polymer, to which an adhesive agent is added. The first substrate 110 and the second substrate 210 may be bonded together by the adhesive matrix 350-1. A plurality of conductive pillars 350-2 may be disposed through the adhesive matrix 350-1. In addition, an insulation layer 350-3 may be coated on sidewall of the conductive pillars 350-2. The insulation layer 350-3 may block electrical connection between the conductive pillars 350-2. A substrate pad 114 and a substrate pad 213 may be electrically connected to each other, and a substrate pad 114′ and substrate pad 213′ may be electrically connected to each other, by means of the conductive pillars 350-2. By performing thermo-compression, the substrate pad 114 may compress the first conductive block 350 to improve electrical connection to the conductive pillars 350-2. The same may apply to the substrate pad 114′, 213, and 213′.

A first portion of the conductive pillars 350-2 may not be used as the electrical channels (connections) to electrically connect the substrate pads 213 and 213′ and 114 and 114′, and a second portion of the conductive pillars 350-2 may be used as the electrical channels (connections) to electrically connect the substrate pads 213 and 213′ and 114 and 114′. The first portion of the conductive pillars 350-2 may have a first length in the vertical direction and the second portion of the conductive pillars 350-2 may have a second length shorter than the first length in the vertical direction.

Referring back to FIG. 6A, a third substrate 310 may be further stacked on the second substrate 210 with a second adhesive conductive block 450 interposed therebetween. The configuration of the second adhesive conductive block 450 and the anisotropic electrical connection characteristic may be identical to that of the first adhesive conductive block 350.

Referring to FIG. 6B, the semiconductor package 300a according to a modification of the third exemplary embodiment may be similar to the semiconductor package 200a depicted in FIG. 4B except for a first conducive block 350a. The first conductive block 350a may electrically connected to the first and second substrates 110a and 210a each other. The first conductive block 350a may have identical configuration and characteristic with the first adhesive conductive block 350 described with reference to FIG. 6A. In addition, a third substrate 310a electrically connected to a third semiconductor chip 320a may be further stacked on the second substrate 210a. A second conductive block 450a may be interposed between the second and third substrates 210a and 310a. The configuration and characteristic of the second conductive block 450a may be identical to that of the first conductive block 350a.

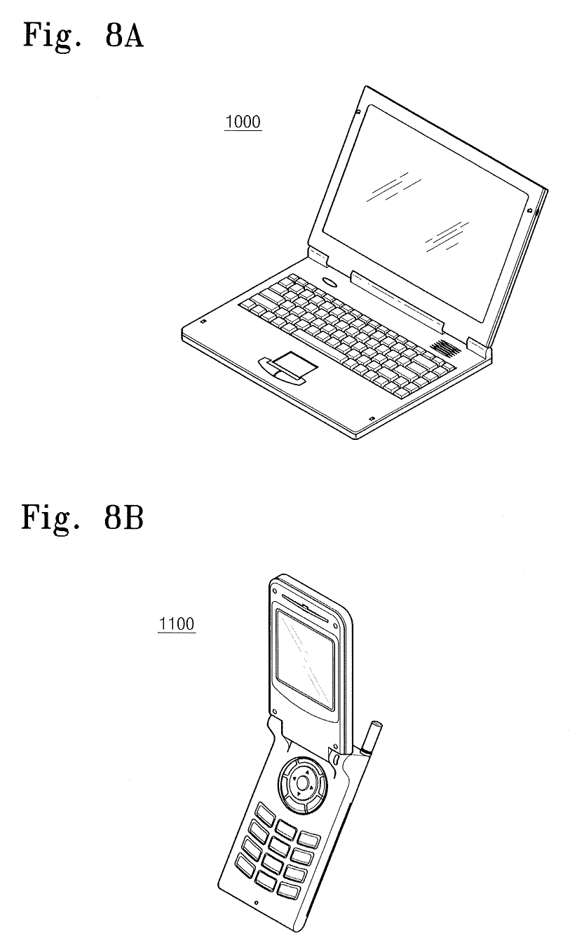

FIGS. 8A and 8B are perspective views of examples of electronic devices where semiconductor package of the exemplary embodiment of the present invention are used.

Referring to FIGS. 8A and 8B, the semiconductor packages described according to the exemplary embodiments of the present invention may be used in electronic devices, for example, lap-top computers 1000 or mobile phones 1100. The electronic devices may also include desktop computers, camcorders, portable multimedia players (PMP), MP3 players, screen displayers such as liquid crystal display (LCD) or plasma display panel (PDP), memory cards and other various devices.

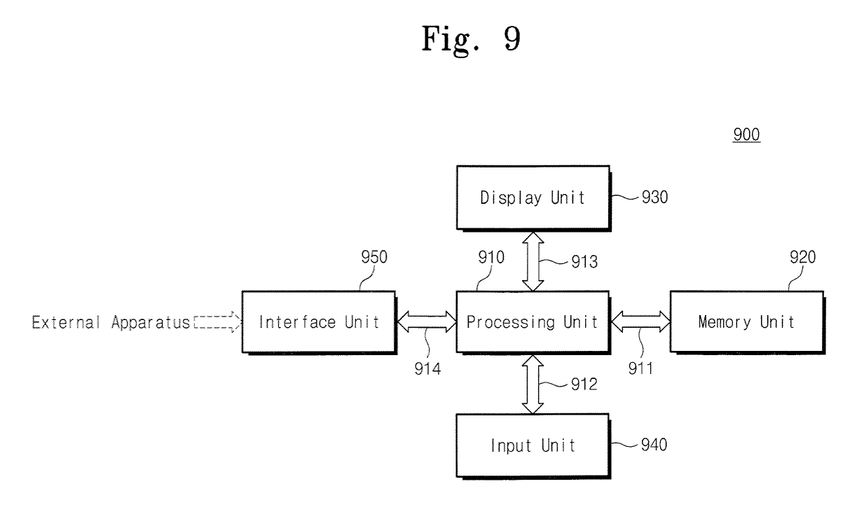

FIG. 9 is a view illustrating an electronic device 900 according to an exemplary embodiment of the present general inventive concept. The electronic device 900 may be a computer, a mobile phone, an apparatus to process a signal to correspond to an image and/or sound, an apparatus to be connected to an external apparatus through a wired or wireless connection or network, an apparatus to communicate with other apparatus to store or exchange data, etc. The electronic device 900 may include a processing unit 910, a memory unit 920, a display unit 930, an input unit 940, and/or an interface unit 950. The semiconductor package 100, 100a, 110b, 200, 200a, 300, and/or 300a of FIGS. 2A-2C, 4A-4B, and 6A-6B can be used as the processing unit 910 and/or the memory unit 920. The external connection terminals 150, 150a, and 150b of FIGS. 2A-2C, 4A-4B, and 6A-6B can be electrically connected to communication lines or terminals 911, 912, 913, and 914 of FIG. 9. The processing unit 910 may process data which is received from the memory unit 920 through the line 911, or the external apparatus through the line 914 and the interface unit 950, and may generate a signal according to the received data or internally generated data so that the display unit displays an image or generates sound as a speaker when the display unit include the speaker or when the display unit is the speaker. The memory unit 920 may store data or program to control the processing unit 910. The input unit 940 may be a key unit to input a signal to control the processing unit 910, the memory unit 920, the display unit 930, and/or the interface unit 950. The electronic device 900 may include a main body to accommodate therein the processing unit 910, the memory unit 920, the display unit 930, the input unit 940, and/or the interface unit 950, and to form an external appearance of the electronic device 900. The interface unit 950 may have one or more terminals to be connectable to the external apparatus. The input unit 940 and/or the display unit 930 may be formed on a surface of the main body of the electronic device to be exposed to an outside thereof. It is also possible that the input unit 940 and/or the display unit 930 may be disposed at an outside of the main body to be connectable to, for example, the lines 913 and 912 and/or the processing unit 910, through a wired or wireless connection.

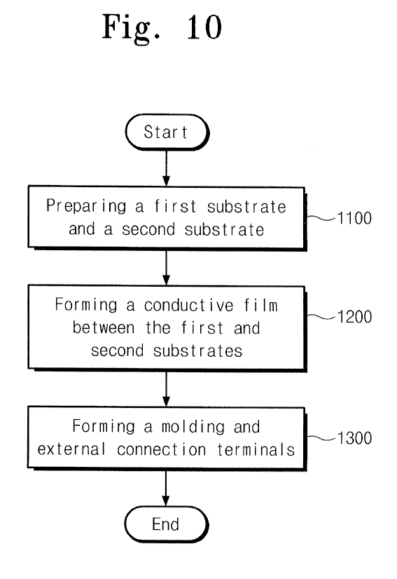

FIG. 10 is a flowchart illustrating a method of forming a semiconductor package and/or an electronic device having the semiconductor package according to an exemplary embodiment of the present general inventive concept. The method is similar to the process or operations to form the semiconductor packages 100, 100a, 110b, 200, 200a, 300, and/or 300a as illustrated in FIGS. 2A-7 and the electronic device of FIGS. 8A-8B, as described above. The method includes preparing a first substrate and a second substrate in operation 1100, forming a conductive film between the first and second substrates in operation 1200, and forming a molding and external connection terminals to complete a semiconductor package in operation 1300. The method may further include connecting the semiconductor package to at least one of the processing unit 910, the memory unit 920, the display unit 930, the input unit 940, and/or the interface unit 950 to form the electronic device.

As described above, the semiconductor package formed according to the exemplary embodiment of the present general inventive concept may include a first semiconductor package having one or more first substrate pads and one or more external connection terminals to be connectable to an external unit, and a second semiconductor package having one or more second substrate pads to be electrically connected to corresponding ones of the one or more first substrate pads.

As described above, the second semiconductor does not have the one or more external connection terminals connectable to the external unit. The one or more external connection terminals of the first semiconductor package are one or more solder balls, and the first substrate pads and the second substrate pads are not the one or more solder balls.

As described above, the semiconductor package may further include an electrical connector interposed between the first semiconductor package and the second semiconductor package to electrically connect the first substrate pads to the second substrate pads. The one or more external connection terminals of the first semiconductor package are one or more solder balls, and the electrical connector is not the one or more solder balls. The first substrate includes a first surface on which the one or more external connection terminals are formed, and a second surface on which the first substrate pads are formed.

As described above, the first semiconductor package includes a first substrate having the first substrate pads, the second semiconductor package includes a second substrate having the second substrate pads to face the first substrate pads, and the electrical connector includes a first connection to electrically connect the first substrate pads to the second substrate pads, and a second connection to connect the first substrate and the second substrate where the first substrate pads and the second substrate pads are not formed. The first connection may have a first length, and the second connection may have a second length longer than the first length.

As described above, the first semiconductor package includes a first substrate having an area where the first substrate pads are formed, and another area when the first substrate pads are nor formed. The second semiconductor package includes a second substrate to face the first substrate, and having an area where the second substrate pads are formed, and another area where the second substrate pads are not formed. The electrical connector may be disposed between the area and the another area of the first substrate and the area and the another area of the second substrate, and may include a first connection to electrically connect the first substrate pads to the second substrate pads, and a second connection to non-electrically connect the another area of the first substrate and the another area of the second substrate.

As described above, an electronic device formed or assembled according to the exemplary embodiment of the present general inventive concept may include a memory unit to store data; and a processing unit to process the data, and at least one of the memory unit and the processing unit may include a first semiconductor package having one or more first substrate pads and one or more external connection terminals to be connectable to an external unit, and a second semiconductor package having one or more second substrate pads to be electrically connected to corresponding ones of the one or more first substrate pads.

Although the present general inventive concept has been described in connection with the embodiment of the present invention illustrated in the accompanying drawings, it is not limited thereto. It will be apparent to those skilled in the art that various substitution, modifications and changes may be thereto without departing from the scope and spirit of the general inventive concept.

What is claimed is:

1. A semiconductor package comprising:
a first semiconductor package;
a second semiconductor package stacked on the first semiconductor package; and
a first electrical connector interposed between the first and second semiconductor packages to electrically connect the first semiconductor package to the second semiconductor package.

2. The semiconductor package of claim 1, wherein the first electrical connector comprises an anisotropic conductive film occupying a space between the first and second semiconductor packages.

3. The semiconductor package of claims 1, wherein the first electrical connector comprises a conductive block occupying a space between the first and second semiconductor packages,

4. The semiconductor package of claim 3, wherein the conductive block comprises:
a ductile matrix occupying a space between the first and second semiconductor packages; and
a conductive pillar inserted through the ductile matrix, both ends of the conductive pillar being connected to the first and second semiconductor packages, respectively.

5. The semiconductor package of claim 4, wherein the conductive block further comprises an insulation layer surrounding sidewall of the conductive pillar.

6. The semiconductor package of claim 3, wherein the first electrical connector further comprises:
a first anisotropic conductive film disposed between the first semiconductor package and the conductive block; and
a second anisotropic conductive film disposed between the second semiconductor package and the conductive block.

7. The semiconductor package of claim 1, wherein at least one of the first and second semiconductor packages comprises:
a semiconductor chip;
a printed circuit board mounted on the semiconductor chip, the printed circuit board including a window that exposes a portion of the semiconductor chip; and
an interconnection through the window configured to electrically connect the semiconductor chip to the printed circuit board.

8. The semiconductor package of claim 1, wherein at least one of the first and second semiconductor packages comprises:
a semiconductor chip;
a printed circuit board mounted on the semiconductor chip; and
an anisotropic conductive film interposed between the semiconductor chip and the printed circuit board that electrically connects the semiconductor chip to the printed circuit board.

9. The semiconductor package of claim 1, wherein at least one of the first and second semiconductor packages comprises:
a sub-semiconductor package including a sub-semiconductor chip and a sub-printed circuit board mounted on the sub-semiconductor chip; and
a printed circuit board electrically connected to the sub-semiconductor package.

10. The semiconductor package of claim 1, wherein the first semiconductor package comprises:
a first surface on which the second semiconductor chip is stacked; and
a second surface, opposed to the first surface, on which an external connection terminal is disposed.

11. The semiconductor package of claim 1, further comprising:
a molding layer occupying a space which is not occupied by the first electrical connector between the first and the second semiconductor packages.

12. The semiconductor package of claim 1, further comprising:
a third semiconductor package stacked on the second semiconductor package; and
a second electrical connector interposed between the second and third semiconductor packages that electrically connects the second semiconductor package to the third semiconductor package.

13. The semiconductor package of claim 12, wherein the second electrical connector is identical to the first electrical connector.

14. A method of fabricating a semiconductor package, the method comprising:
providing a first and a second semiconductor packages;
providing an electrical connector between the first and second semiconductor packages; and
compressing the electrical connector so as to electrically connect the first semiconductor package to the second semiconductor package through the compressed electrical connector.

15. The method of claim 14, wherein providing the electrical connector comprises interposing an anisotropic conductive film between the first and the second semiconductor packages.

16. The method of claim 14, wherein providing the electrical connector comprises:
attaching a first anisotropic conductive film to the first semiconductor package;
attaching a second anisotropic conductive film to the second semiconductor package so as to face the first anisotropic conductive adhesive film; and
providing a conductive block between the first and second anisotropic conductive films.

17. The method of claim 14, wherein providing the electrical connector comprises interposing the conductive block between the first and second semiconductor packages.

18. The method of claim 14, further comprising:
attaching an external connection terminal on one of the first and second semiconductor packages.

19. The method of claim 14, further comprising:
forming a molding layer configured to mold the first and second semiconductor packages, and to fill a space which is not filled by the electrical connector between the first and second semiconductor packages.

20. A method of fabricating a semiconductor package, the method comprising:
providing a first semiconductor package and a second semiconductor package stacked on the first semiconductor package; and
interposing a first electrical connector between the first and second semiconductor packages to electrically connect the first semiconductor package to the second semiconductor package.

21. A semiconductor package comprising:
a first semiconductor package having one or more first substrate pads and one or more external connection terminals to be connectable to an external unit; and
a second semiconductor package having one or more second substrate pads to be electrically connected to corresponding ones of the one or more first substrate pads.

22. The semiconductor package of claim 21, wherein the second semiconductor does not have the one or more external connection terminals connectable to the external unit.

23. The semiconductor package of claim 21, wherein the one or more external connection terminals of the first semiconductor package are one or more solder balls, and the first substrate pads and the second substrate pads are not the one or more solder balls.

24. The semiconductor package of claim 21, further comprising:
an electrical connector interposed between the first semiconductor package and the second semiconductor package to electrically connect the first substrate pads to the second substrate pads.

25. The semiconductor package of claim 24, wherein the one or more external connection terminals of the first semiconductor package are one or more solder balls, and the electrical connector is not the one or more solder balls.

26. The semiconductor package of claim 24, wherein the first substrate comprises a first surface on which the one or more external connection terminals are formed, and a second surface on which the first substrate pads are formed.

27. The semiconductor package of claim 24, wherein:
the first semiconductor package comprises a first substrate having the first substrate pads;
the second semiconductor package comprises a second substrate having the second substrate pads to face the first substrate pads; and
the electrical connector comprises a first connection to electrically connect the first substrate pads to the second substrate pads, and a second connection to connect the first substrate and the second substrate where the first substrate pads and the second substrate pads are not formed.

28. The semiconductor package of claim 27, wherein the first connection has a first length, and the second connection has a second length longer than the first length.

29. The semiconductor package of claim 24, wherein:
the first semiconductor package comprises a first substrate having an area where the first substrate pads are formed, and another area when the first substrate pads are nor formed;
the second semiconductor package comprises a second substrate to face the first substrate, and having an area where the second substrate pads are formed, and another area where the second substrate pads are not formed; and
the electrical connector is disposed between the area and the another area of the first substrate and the area and the another area of the second substrate, and comprises a first connection to electrically connect the first substrate pads to the second substrate pads, and a second connection to non-electrically connect the another area of the first substrate and the another area of the second substrate.

30. An electronic device comprising:
a memory unit to store data; and
a processing unit to process the data,
wherein at least one of the memory unit and the processing unit comprises:
a first semiconductor package having one or more first substrate pads and one or more external connection terminals to be connectable to an external unit; and
a second semiconductor package having one or more second substrate pads to be electrically connected to corresponding ones of the one or more first substrate pads.
